(19) United States
(12) Patent Application Publication
(10) Pub. No.: US 2025/0194336 A1
(43) Pub. Date: Jun. 12, 2025

(54) DISPLAY DEVICE

(71) Applicant: LG Display Co., Ltd., Seoul (KR)

(72) Inventors: Mi-Na KIM, Paju-si (KR); Moonsung KIL, Paju-si (KR); Eunhyung LEE, Paju-si (KR); YongCheol KIM, Paju-si (KR)

(21) Appl. No.: 18/796,032

(22) Filed: Aug. 6, 2024

(30) Foreign Application Priority Data
Dec. 7, 2023 (KR) 10-2023-0176922

(51) Int. Cl. H10K 50/12; H10K 50/19; H10K 59/35

(52) U.S. Cl. CPC H10K 50/12; H10K 50/19; H10K 59/353

(57) ABSTRACT

The present disclosure provides to a display device having a structure where a proportion of a p-type host in an emission layer located in a second active area having a second resolution lower than a first resolution is set to be greater than that in an emission layer located in a first active area having the first resolution, and thereby, providing advantages of being driven with low power by reducing a difference in luminance between an area where low-resolution pixels are disposed and an area where high-resolution pixels are disposed.

### CROSS-REFERENCE TO RELATED APPLICATION

This application claims the priority benefit of Republic of Korea Patent Application No. 10-2023-0176922, filed on Dec. 7, 2023 in the Korean Intellectual Property Office, which is incorporated herein by reference for all purposes as if fully set forth herein.

### BACKGROUND

### Technical Field

The present disclosure relates to electronic devices with displays, and more specifically, to display devices.

### Description of the Related Art

Light emitting displays are generally classified into organic light emitting displays and inorganic light emitting displays based on a material of an emission layer.

Organic light emitting displays of an active matrix type include self-emissive organic light emitting diodes and have advantages of a short response time, high luminous efficiency, excellent luminance, a wide viewing angle, and the like.

In organic light emitting displays, one or more organic light emitting diodes may be disposed in each pixel thereof. Organic light emitting displays provide advantages of not only a short response time, excellent luminous efficiency, high luminance, and a wide viewing angle, but high contrast ratio and excellent color gamut because a black gray level can be expressed as complete black.

In modern society, mobile terminals are widely used, and multimedia functions for implementing various functions or applications necessary in daily life through mobile terminals are becoming increasingly improved.

For example, a camera has been embedded into smart phones by default, and recently, a camera with resolution close to the resolution of a conventional digital camera has been applied to smart phones.

However, a front camera embedded into smart phones can impose a limit on the size and design of the screen; thus, this makes it difficult to design the screen wider and more freely.

To reduce a corresponding space occupied by the camera, a screen design including a notch or punch hole has been adopted in smart phones. However, in these implementations, the screen size may be still limited due to the camera, and thus, there is a need for implementing a full-screen display.

The full-screen display may refer to an image display implementation of a display device in which an image can be displayed across most of the front surface of mobile terminals such as smart phones.

### BRIEF SUMMARY

To realize full-screen display in a display device, there may be provided a scheme of assigning an area for disposing low-resolution pixels in a screen area of a display panel, and disposing a camera and/or various sensors in an area of the display device that is located under the display panel and opposite to the area where the low-resolution pixels are disposed.

However, since pixels are still present in the area where the low-resolution pixels are disposed, and corresponding light emitting areas become reduced, more than 1.5 times current needed for driving the low-resolution pixels may be required to maintain the same luminance.

As an amount of required current increases, the lifetime of the pixels may be reduced. Thereby, as time passes, a difference in luminance between the area where the low-resolution pixels are disposed and an area where high-resolution pixels are disposed may become great, and in turn, a boundary of the area where the low-resolution pixels are disposed may be clearly recognized.

To address these issues, the inventors of the present disclosure have provided various embodiments of a display device capable of reducing a difference in luminance between an area where low-resolution pixels are disposed and an area where high-resolution pixels are disposed even when the low-resolution pixels are used for a long time by enabling the low-resolution pixels to have increased lifetime.

One or more aspects of the present disclosure may provide a display device capable of reducing a difference in luminance between an area where low-resolution pixels are disposed and an area where high-resolution pixels are disposed.

According to one or more example embodiments of the present disclosure, a display device can be provided that includes: a first active area in which a plurality of first pixels are disposed, the first active area having a first resolution; a second active area in which a plurality of second pixels are disposed, the second active area having a second resolution less than the first resolution; and a plurality of light emitting elements disposed in each of the plurality of first pixels and the plurality of second pixels. Each of the plurality of light emitting elements may include a first electrode layer, a second electrode layer, and an emission that is located between the first electrode layer and the second electrode layer and is any one of a red emission layer, a green emission layer, and a blue emission layer. The emission layer may include at least one of a p-type host and an n-type host, and at least one of the red emission layer, the green emission layer, and the blue emission layer may be configured to satisfy the following equation:

$${p}_{1} / ( {n}_{1} + {p}_{1} ) < {p}_{2} / ( {n}_{2} + {p}_{2} ) \qquad Equation 1$$

where, p₁ is the number of moles of the p-type host of the emission layer located in the first active area, p₂ is the number of moles of the p-type host of the emission layer located in the second active area, n₁ is the number of moles of the n-type host of the emission layer located in the first active area, and n₂ is the number of moles of the n-type host of the emission layer located in the second active area.

According to one or more example embodiments of the present disclosure, a display device can be provided that includes: a first active area in which a plurality of first pixels are disposed, the first active area having a first resolution; a second active area in which a plurality of second pixels are disposed, the second active area having a second resolution less than the first resolution; and a plurality of light emitting elements disposed in each of the plurality of first pixels and the plurality of second pixels. Each of the plurality of light emitting elements may include a first electrode layer, a second electrode layer, and an emission that is located between the first electrode layer and the second electrode layer and is any one of a red emission layer, a green emission layer, and a blue emission layer. The emission layer may include at least one of a p-type host and an n-type host. At least one of the red emission layer, the green emission layer, and the blue emission layer, which are located in the second active area, may include a first layer including the p-type host and the n-type host, and a second layer located on a surface of the first layer and including the p-type host. At least one of the red emission layer, the green emission layer, and the blue emission layer, which are located in the first active area, may include a first layer including the p-type host and the n-type host.

According to one or more aspects of the present disclosure, a display device may be provided that is capable of reducing a difference in luminance between an area where low-resolution pixels are disposed and an area where high-resolution pixels are disposed, and thereby, enabling low power operation.

### BRIEF DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 schematically illustrates an example display device according to aspects of the present disclosure;

FIG. 2 is an example cross-sectional view of the display device according to aspects of the present disclosure;

FIG. 3 illustrates a plurality of first pixels disposed in a first active area of the display device according to aspects of the present disclosure;

FIG. 4 illustrates a plurality of second pixels disposed in a second active area of the display device according to aspects of the present disclosure;

FIGS. 5A and 5B are cross-sectional views of example light emitting elements included in the display device according to aspects of the present disclosure;

FIG. 6A is a cross-sectional view of example light emitting elements included in each first pixel of the display device according to aspects of the present disclosure;

FIGS. 6B and 6C are cross-sectional views of example light emitting elements included in each second pixel of the display device according to aspects of the present disclosure;

FIG. 7A is another cross-sectional view of example light emitting elements included in a first pixel of the display device according to aspects of the present disclosure;

FIGS. 7B and 7C are other cross-sectional views of example light emitting elements included in a second pixel of the display device according to aspects of the present disclosure;

FIG. 8 is a front view of an example thin film deposition apparatus used for manufacturing light emitting elements according to aspects of the present disclosure;

FIG. 9 is a graph showing the lifetime and intensity of a green subpixel with respect to p-type host ratios in the display device according to aspects of the present disclosure;

FIG. 10 is a graph showing the lifetime of a green subpixel with respect to a p-type host molar ratio of a second active area to a first active area in the display device according to aspects of the present disclosure; and

FIG. 11 is a graph showing a pixel area ratio of a second active area to a first active area with respect to a p-type host molar ratio of the second active area to the first active area in the display device according to aspects of the present disclosure.

### DETAILED DESCRIPTION

Reference will now be made in detail to example embodiments of the present disclosure, examples of which may be illustrated in the accompanying drawings.

In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

The text “at least one of A and B” as used herein should be understood to mean “only A, only B, or both A and B.”

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, with reference to the accompanying drawings, various example embodiments of the present disclosure will be described in detail.

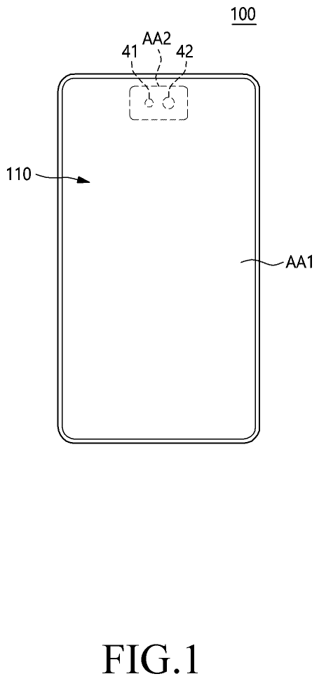

FIG. 1 schematically illustrates an example display device 100 according to aspects of the present disclosure.

Referring to FIG. 1, in one or more example embodiments, the display device 100 may include a display panel 110 and a case (or housing).

The front of the display panel 100 may be configured with a display area.

A full-screen display can be enabled by applying this implementation.

The display area may include a first active area AA1 and a second active area AA2.

Both the first active area AA1 and the second active area AA2 may be configured to present images, but respective resolutions of the first active area AA1 and the second active area AA2 may be different.

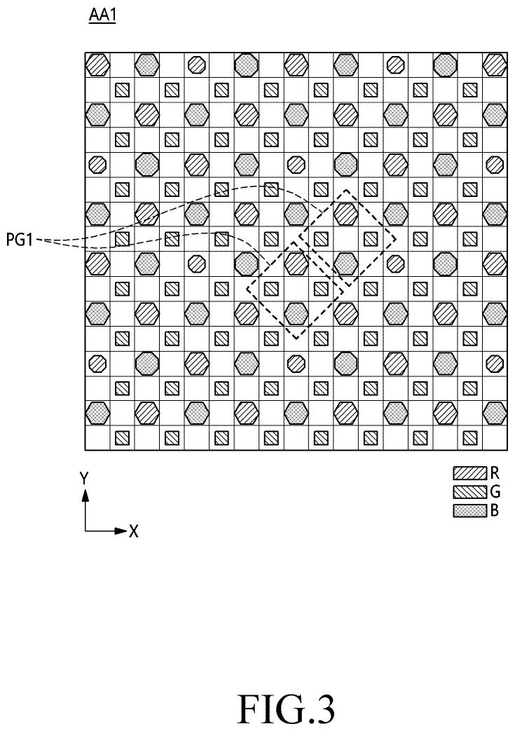

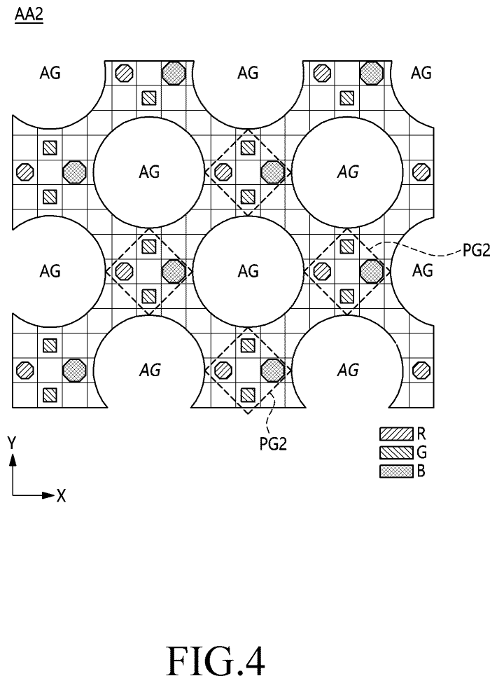

For example, the resolution of the second active area AA2 in which a plurality of second pixels PG2 are disposed may be lower than the resolution of the first active area AA1 in which a plurality of first pixels PG1 are disposed. It can also be said that the density of a plurality of second pixels PG2 in the second active area AA2 is lower than a density of a plurality of first pixels PG1 in the first active area AA1 as shown in FIGS. 3 and 4. FIG. 4, for instance, shows the density of the plurality of second pixels PG2 in the second active area AA2 having a lower density as compared to the density of the plurality of first pixels PG1 in the first active area AA1 due to the presence of one or more light transmissive areas AG. This will be explained in detail in connection with FIGS. 3 and 4 below. An amount of light corresponding to a degree to which the resolution of the second active area AA2 including the plurality of second pixels is lowered may be allowed to reach one or more sensors (41, 42) disposed in the second active area AA2.

However, example embodiments of the present disclosure are not limited thereto. For example, when the second active area AA2 has a sufficient light transmittance, or a suitable noise compensation algorithm is implemented, the resolution of the second active area AA2 may be the same or substantially the same as the resolution of the first active area AA1.

For the purpose of description, discussions are provided based on examples where the resolution of the second active area AA2 of the display panel 110 is lower than that of the first active area AA1.

In one or more aspects, the second active area AA2 included in the display panel 110 may be an area in which one or more sensors (41, 42) are disposed.

The second active area AA2 may be an area overlapping one or more sensors. Therefore, the second active area CA may have a size smaller than the first active area AA1 in which most of images presented in the display area are presented.

The sensor (41, 42) may include at least one of an image sensor, a proximity sensor, an illuminance sensor, a gesture sensor, a motion sensor, a fingerprint recognition sensor, and a biometric sensor.

For example, the one or more sensors (41, 42) disposed in the second active area AA2 may include a first sensor 41 such as an illuminance sensor, and a second sensor 42 such as an image sensor for capturing images or videos. However, example embodiments of the present disclosure are not limited thereto.

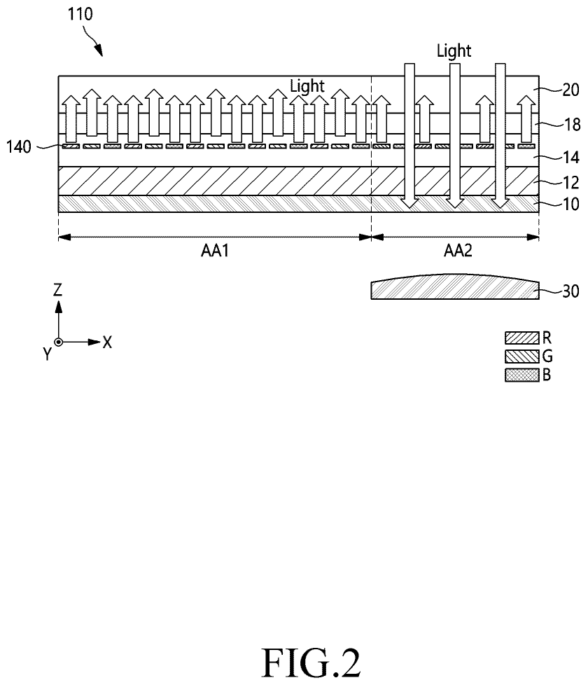

FIG. 2 is an example cross-sectional view of the display device 100 according to aspects of the present disclosure.

Referring to FIG. 2, each of the first active area AA1 and the second active area AA2 may include one or more pixel arrays in which a plurality of pixels capable of emitting light depending on pixel data are disposed.

A plurality of first pixels PG1 or a plurality of second pixels PG2 may represent a pixel array.

Herein, the term “resolution” may mean the number of pixels per unit area (which may referred to as pixels per inch (PPI)). For example, to increase a light transmittance of the second active area AA2, the number of pixels per unit area of the second active area AA2 may be lower than the number of pixels per unit area of the first active area AA1.

A plurality of pixels, which are configured with a relatively large number of pixels per unit area, may be disposed in each of one or more pixel arrays included in the first active area AA1.

The number of pixels per unit area in the first active area AA1 may be 400 ppi or more, but example embodiments of the present disclosure are not limited thereto.

In contrast, a plurality of pixel groups, which are spaced apart by one or more light transmissive areas AG and configured with a relatively small number of pixels per unit area, may be disposed in each of one or more pixel arrays included in the second active area AA2.

The number of pixels per unit area of the second active area AA2 may be 200 ppi or less, but example embodiments of the present disclosure are not limited thereto.

In the second active area AA2, external light can pass through the display panel 110 through one or more light transmissive areas AG with a high light transmittance and be received by a sensor located under the display panel 110.

Since both the first active area AA1 and the second active area AA2 include pixels, input images can be presented in both the first active area AA1 and the second active area AA2.

Each of pixels disposed in each of the first active area AA1 and the second active area AA2 may include subpixels of different colors to represent color images.

The subpixels may include a red subpixel R, a green subpixel G, and a blue subpixel B.

It should be noted that although the subpixels may further include a white subpixel, FIG. 2 illustrates an example where a pixel includes a red subpixel R, a green subpixel G, and a blue subpixel B for simplicity.

One or more aspects, each subpixel may include a pixel circuit and a light emitting element, such as a light emitting diode (OLED), or the like.

The second active area AA2 may include pixels and one or more sensors disposed under, or a lower portion of, the display panel 110.

As described above, the sensor may include various types of sensors. Hereinafter, for convenience of description, discussions are provided based on examples whereas an example of the sensor, a camera module is disposed in the display device 100.

As pixel data based on input image data are written in second pixels PG2 disposed in the second active area AA2 in a display mode, the second pixels PG2 can emit light corresponding to the pixel data to display images in the display area of the display panel 110.

The camera module can capture external images in an imaging mode and output photo or video data.

A lens 30 of the camera module may face the second active area AA2.

External light can incident on the lens 30 of the camera module through the second active area AA2, and the lens 30 can focus the light on an image sensor.

The camera module can capture external images in the imaging mode and output photo or video data.

As the number of pixels per unit area of one or more pixel arrays in the second active area AA2 is relatively low to achieve high light transmittance, an image quality compensation algorithm may be applied to compensate for luminance and color coordinates of pixels in the second active area AA2.

Therefore, a full screen display can be implemented without a limitation on the display area of the display panel 110 due to the camera module disposed under, or a lower portion of, the display panel 110.

The display panel has a width in an x-axis direction, a length in a y-axis direction, and a thickness in a z-axis direction.

The display panel 110 may include a circuit layer 12 disposed on a substrate 10 and a light emitting element layer 14 disposed on the circuit layer 12.

An encapsulation layer 18 may be disposed on the light emitting element layer 14, and a cover glass 20 may be disposed on the encapsulation layer 18.

In one or more aspects, a polarizer may be disposed between the encapsulation layer 18 and the cover glass 20 to improve visibility of the display device 100 in bright environments.

The circuit layer 12 may include a pixel circuit connected to lines, such as data lines, gate lines, power lines, and the like, and a gate driver connected to the gate lines.

The circuit layer 12 may include circuit elements such as one or more transistors (which may be thin film transistors (TFT)), at least one capacitor, and the like, and lines.

The lines and circuit elements of the circuit layer 12 may be implemented or formed by a plurality of insulating layers, two or more metal layers separated by an insulating layer interposed therebetween, and an active layer including a semiconductor material.

The light emitting element layer 14 may include a light emitting element driven by the pixel circuit.

The light emitting element layer 14 may be covered by the encapsulation layer 18.

The encapsulation layer 18 may have a structure in which at least one organic layer and at least one inorganic layer are alternately stacked.

The inorganic layer can prevent the penetration of moisture or oxygen, and the organic layer may be configured to flatten a surface of the inorganic layer.

As a traveling path of moisture or oxygen in the stacking structure of one or more organic layers and one or more inorganic layers becomes longer than that in a structure having a single layer, the encapsulation layer 18 can effectively prevent the penetration of moisture and oxygen affecting the light emitting element layer 14.

FIG. 3 illustrates a plurality of first pixels PG1 disposed in a first active area AA1 of the display device 100 according to aspects of the present disclosure.

Referring to FIG. 3, the first active area AA1 may include a plurality of first pixels PG1 arranged in a matrix form.

Each of the first pixels PG1 may be implemented as one unit pixel by including two or more subpixels among a red subpixel R, a green subpixel G, and a blue subpixel B.

In one or more aspects, each of the plurality of first pixels PG1 may further include a white subpixel.

In one or more aspects, two subpixels can be implemented as one pixel by a subpixel rendering algorithm.

For example, each of one or more of the first pixels PG1 may be configured to include a red subpixel R and a green subpixel G.

In another example, each of one or more of the first pixels PG1 may be configured to include a blue subpixel B and a green subpixel G.

In these examples, such insufficient color representation in each of the first pixels PG1 may be compensated for based on an average value of corresponding color data of neighboring pixels through a subpixel rendering algorithm.

FIG. 3 illustrates that subpixels are disposed such that a red subpixel R, a green subpixel G, a blue subpixel B, and a green subpixel G are disposed in a zigzag form in the x-axis direction, but example embodiments of the present disclosure are not limited thereto.

FIG. 4 illustrates a plurality of second pixels PG2 disposed in a second active area AA2 of the display device 100 according to aspects of the present disclosure.

Referring to FIG. 4, a plurality of light transmissive areas AG may be disposed in the second active area AA2. Each of the plurality of light transmissive areas AG may be disposed between a plurality of second pixels PG2.

The light transmissive areas AG may include one or more transparent materials having high light transmittance without including a metal for allowing light to reach the light transmissive areas AG at a minimized or reduced loss.

In one or more aspects, the light transmissive areas AG may include a transparent insulating material without including metal lines or pixels.

FIG. 4 illustrates that the shape of the light transmissive areas AG is circular, but example embodiments of the present disclosure are not limited thereto.

For example, the light transmissive areas AG may be designed in various shapes such as a circle, an ellipse, a polygon, and the like.

Except for configurations related to dopants, which are described below, configurations of the second pixels PG2 may be substantially the same as those of the first pixels PG1 described in FIG. 3, and thus, discussions on such configurations of the second pixels PG2 are omitted for convenience of description.

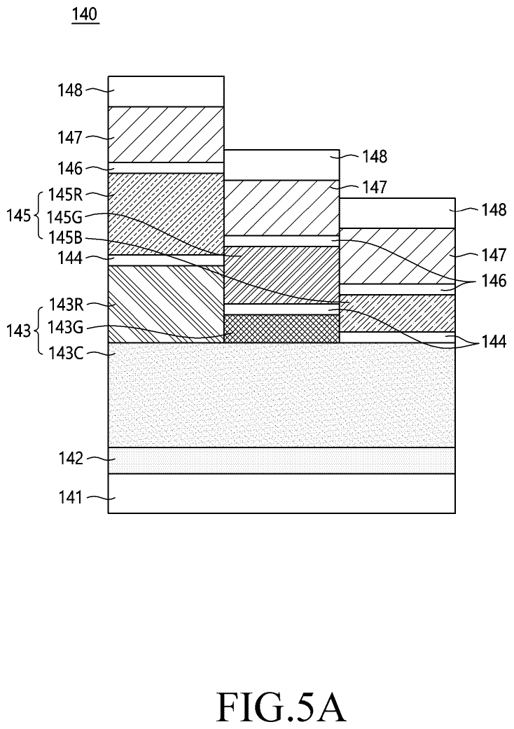

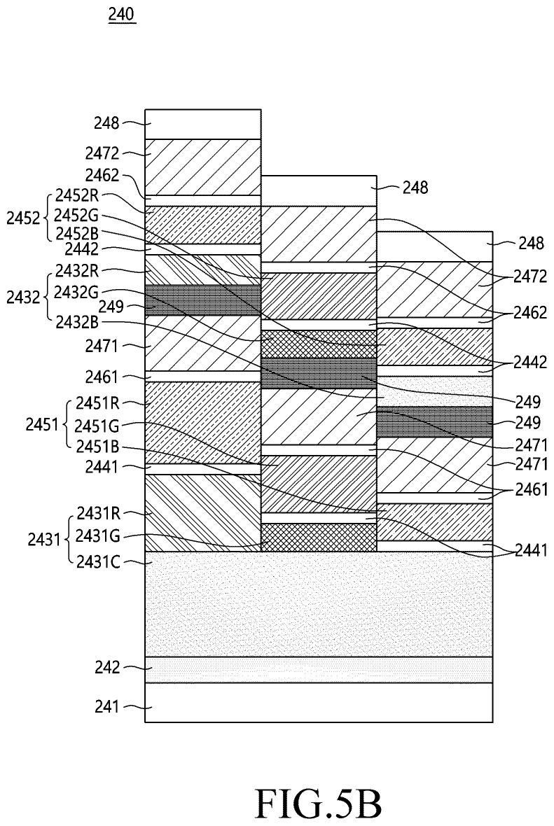

FIGS. 5A and 5B are cross-sectional views of example light emitting elements 140 included in the display device 100 according to aspects of the present disclosure.

Referring to FIG. 5A, in one or more example embodiments, a stack of light emitting elements 140 included in the display device 100 may include respective portions of a red subpixel R, a green subpixel G, and a blue subpixel B, which are disposed on a substrate 10 and configured to emit different colors.

The stack of the light emitting elements 140 may include a first electrode layer 141 disposed on the substrate 10, a second electrode layer 148 disposed opposite to the first electrode layer 141, and an emission layer 145 disposed between the first electrode layer 141 and the second electrode layer 148.

The first electrode layer 141 may be an anode, and the second electrode layer 148 may be a cathode, but example embodiments of the present disclosure are not limited thereto.

For example, in the case of an inverted type, the first electrode layer 141 may be a cathode and the second electrode layer 148 may be an anode.

It should be noted hereinafter that discussions are provided based on examples where first and second electrode layers (141 and 148) of each light emitting element 140 are an anode and a cathode, respectively.

At least one transistor (not shown in FIG. 5A) disposed over the substrate 10 may include a source, drain, gate, and active layer, and the first electrode layer 141 may be electrically connected to any one of the source and the drain of the transistor through a contact hole formed in an insulating layer disposed on the substrate 10.

The first electrode layer 141 may include a material with a relatively high work function.

The first electrode layer 141 may include, for example, a transparent conductive oxide, such as indium tin oxide (ITO), indium zinc oxide (IZO), zinc oxide (ZnO), aluminum zinc oxide (AZO), indium oxide (In₂O₃), tin oxide (SnO₂), or the like, but example embodiments of the present disclosure are not limited thereto.

The second electrode layer 148 may include a material with a relatively low work function, for example, a metal, an alloy, an electroconductive compound, or a mixture of two or more thereof.

For example, a transmissive electrode as the second electrode layer 58 may be obtained by forming, in the form of a thin film, lithium (Li), magnesium (Mg), aluminum (Al), aluminum-lithium (Al—Li), calcium (Ca), magnesium-indium (Mg—In), magnesium-silver (Mg—Ag), or the like.

In this regard, in one or more aspects, various modifications may be made, such as forming a transmissive electrode using ITO or IZO to obtain a top emission light emitting element.

A capping layer (not shown in FIG. 5A) may be disposed on the second electrode layer 148 to improve optical capability and maximize emission efficiency.

For example, the capping layer may include a metal oxide layer, a metal nitride layer, or a metal nitride layer.

For example, the capping layer may include MoOₓ (x=2˜4), Al₂O₃, Sb₂O₃, BaO, CdO, CaO, Ce₂O₃, CoO, Cu₂O, DyO, GdO, HfO₂, La₂O₃, Li₂O, MgO, NbO, NiO, Nd₂O₃, PdO, Sm₂O₃, ScO, SiO₂, SrO, Ta₂O₃, TiO, WO₃, VO₂, YbO, Y₂O₃, ZnO, ZrO, AlN, BN, NbN, SiN, TaN, TiN, VN, YbN, ZrN, SiON, AlON, or mixtures thereof, but example embodiments of the present disclosure are not limited thereto.

Referring to FIG. 5A, the emission layer 145 of the stack of the light emitting elements 140 may include a red emission layer 145R of the red subpixel R, a green emission layer 145G of the green subpixel G, and a blue emission layer 145B of the blue subpixel B.

For example, wavelengths of light emitted from the emission layers (145R, 145B, and 145B) may be, in a descending length order, the red emission layer 145R, the green emission layer 145G, and the blue emission layer 145B.

The red emission layer 145R may include a red host and a red dopant.

The red host may use Alq3, CBP, PVK, AND, TCTA, TPBI, TBADN, E3, DSA, or a mixture of two or more thereof, but example embodiments of the present disclosure are not limited thereto.

The red dopant may use PtOEP, Ir(piq)₃, Btp₂Ir(acac), Ir(2-phq)₂(acac), Ir(2-phq)₃, Ir(flq)₂(acac), Ir(fliq)₂(acac), or compounds containing DCM or DCJTB, but example embodiments of the present disclosure are not limited thereto.

The green emission layer 145G may include a green host and a green dopant.

The green host may use Alq3, CBP, PVK, AND, TCTA, TPBI, TBADN, E3, DSA, or a mixture of two or more thereof, but example embodiments of the present disclosure are not limited thereto.

The green dopant may use Ir(ppy)₃ tris(2-phenylpyridine) iridium, Ir(ppy)₂(acac)(Bis(2-phenylpyridine)(Acetylacetonato)iridium(III), Ir(mppy)₃ (tris(2-(4-tolyl)phenylpiridine)iridium, C545T 10-(2benzothiazolyl)-1,1,7,7-tetramethyl-2,3,6,7-tetrahydro-1H,5H,11H-[1]benzopyrano[6,7,8-ij]-quinolizin11-one, or the like, but example embodiments of the present disclosure are not limited thereto.

The blue emission layer 145B may include a blue host and a blue dopant.

The blue host may use Alq3, CBP (4,4′-N,N′-dicabazole-biphenyl), PVK (poly(n-vinylcabazole), ADN (9,10-di(naphthalene-2-yl)anthracene), TCTA, TPBI (1,3,5-tris(N-phenylbenzimidazole-2-yl)benzene), TBADN (3-tert-butyl-9,10-di(naphth-2-yl)anthracene), E3, DSA (distyrylarylene), or a mixture of two or more thereof, but example embodiments of the present disclosure are not limited thereto.

The blue dopant may use compounds containing F₂Irpic, (F₂ppy)₂Ir(tmd), Ir(dfppz)₃, ter-fluorene, DPAVBi (4,4′-bis(4diphenylaminostyryl)biphenyl, TBPe, and/or the like, but example embodiments of the present disclosure are not limited thereto.

Referring to FIG. 5A, the stack of the light emitting elements 140 may include a hole transport layer 143 disposed between the first electrode layer 141 and the emission layer 145.

The hole transport layer 143 may include a common hole transport layer 143C disposed on a hole injection layer 142.

The hole transport layer 143 may include an emission auxiliary layer disposed between the hole transport layer 143 and the common hole transport layer 143C.

The emission auxiliary layer may include a red emission auxiliary layer 143R, a green emission auxiliary layer 143G, and a blue emission auxiliary layer (not shown) disposed on the hole transport layer 143C.

For example, the emission auxiliary layer may serve to transport holes and may include a hole transport material. The emission auxiliary layers may include the same material or compound, or may include different materials or compounds.

For example, the hole transport layer 143, the common hole transport layer 143C, the red emission auxiliary layer 143R, the green emission auxiliary layer 143G, and the blue emission auxiliary layer (not shown) may include materials containing tertiary amines or tertiary amines containing fluorene, but example embodiments of the present disclosure are not limited thereto.

Referring to FIG. 5A, the stack of the light emitting elements 140 may include the hole injection layer 142 disposed on the first electrode layer 141, the hole transport layer 143 disposed on the hole injection layer, the emission layer 145 disposed on the hole transport layer 143, and an electron transport layer 147 disposed on the emission layer 145, but example embodiments of the present disclosure are not limited thereto.

When a voltage is applied between the first electrode layer 141 and the second electrode layer 148 of the stack of the light emitting elements 140, holes passing through the hole transport layer 143 and electrons passing through the electron transport layer 147 can move to the emission layer 145 and form excitons, this enabling the emission layer 145 to emit visible light.

Referring to FIG. 5A, the stack of the light emitting elements 140 may include an electron blocking layer 144 between the hole transport layer 143 and the emission layer 145.

However, example embodiments of the present disclosure are not limited thereto. For example, the stack of the light emitting elements 140 may not include the electron blocking layer 144.

The electron blocking layer 144 may include at least one of Tris(phenylpyrazole)iridium, BPAPF (9,9-bis[4-(N,N-bis-biphenyl-4-ylamino)phenyl]-9H-fluorene), Bis[4-(p,p-ditolylamino)phenyl]diphenylsilane, NPD (4,4′-bis[N-(1-napthyl)-N-phenyl-amino]biphenyl), mCP (N,N′-dicarbazolyl-3,5-benzene), and MPMP (bis[4-(N,N-diethylamino)-2-methylphenyl](4-methylphenyl)methane), or a combination thereof, but example embodiments of the present disclosure are not limited thereto.

In one or more aspects, the electron blocking layer 144 may include an inorganic compound. For example, the electron blocking layer 144 may include at least one of a halide compound such as LiF, NaF, KF, RbF, CsF, FrF, MgF₂, CaF₂, SrF₂, BaF₂, LiCl, NaCl, KCl, RbCl, CsCl, FrCl, or the like, and an oxide such as Li₂O, Li₂O₂, Na₂O, K₂O, Rb₂O, Rb₂O₂, Cs₂O, Cs₂O₂, LiAlO₂, LiBO₂, LiTaO₃, LiNbO₃, LiWO₄, Li₂CO, NaWO₄, KAlO₂, K₂SiO₃, B₂O₅, Al₂O₃, SiO₂, or the like, or include a combination of the halide compound and the oxide. However, example embodiments of the present disclosure are not limited thereto.

The electron blocking layer 144 can serve as a buffer layer for blocking direct contact between the hole transport layer 143 and the emission layer 145, and serve to prevent electrons from easily flowing into the hole transport layer 143.

For example, the electron blocking layer 144 can improve the efficiency and lifetime of the light emitting elements 140 by controlling injection and movement of electrons, and combination of electrons and holes.

The electron transport layer 147 may be disposed on the emission layer 145.

The electron transport layer 147 can control a movement speed of electrons so that electrons and holes can meet in the emission layer 145 and enable the emission layer 145 to emit light.

The electron transport layer 147 may include a material allowing electrons to move at a speed several times higher than a speed at which other materials allows electrons to move.

The electron transport layer 147 may include, for example, at least one of Alq3 (tris(8-hydroxyquinolino)aluminum), PBD, TAZ, spiro-PBD, BAlq, and SAlq, or a combination thereof, but example embodiments of the present disclosure are not limited thereto.

An electron injection layer (not shown) may be disposed on the electron transport layer 147.

The electron injection layer (not shown) can transfer electrons flowing from the second electrode layer 148 to the electron transport layer 147.

Referring to FIG. 5A, the stack of the light emitting elements 140 may include a hole blocking layer 146 between the emission layer 145 and the electron transport layer 147.

However, example embodiments of the present disclosure are not limited thereto. For example, the stack of the light emitting elements 140 may not include the hole blocking layer 146.

The hole blocking layer 146 can serve as a buffer layer for blocking direct contact between the electron transport layer 147 and the emission layer 145, and serve to prevent holes from easily flowing into the electron transport layer 147.

For example, the hole blocking layer 146 can improve the efficiency and lifetime of the light emitting elements 140 by controlling injection and movement of holes, and combination of holes and electrons.

As described above, an example where each light emitting element has a single stack structure has been described with reference to FIG. 5A.

Hereinafter, another example where each light emitting element 240 has a multi-stack structure is described with reference to FIG. 5B.

Referring to FIG. 5B, in one or more example embodiments, each light emitting element ED has a multi-stack structure including a first emission layer 2451 and a second emission layer 2452.

For example, the first emission layer 2451 and the second emission layer 2452 may include an emission material capable of emitting the same color.

Referring to FIG. 5B, each light emitting element 240 may be configured with a first stack structure including the first emission layer 2451, and a second stack structure including the second emission layer 2452.

A first hole transport layer 2431, a first electron blocking layer 2441, the first emission layer 2451, a first hole blocking layer 2461, and a first electron transport layer 2471 included in the first stack structure may be the same, or substantially the same, as the hole transport layer 143, the electron blocking layer 144, the emission layer 145, the hole blocking layer 146, and electron transport layer 147 of FIG. 5A, respectively. Thus, for simplicity, discussions on these elements are omitted.

In one or more aspects, in the second stack structure, a charge generation layer 249, a second hole transport layer 2432, a second electron blocking layer 2442, the second emission layer 2452, a second hole blocking layer 2462, and a second electron transport layer 2472 may be disposed between a second electrode layer 248 and the first electron transport layer 2471.

In one or more aspects, the charge generation layer 249 may be located on the first electron transport layer 2471, the second hole transport layer 2432 may be located on the charge generation layer 249, the second electron blocking layer 2442 may be located on the second hole transport layer 2432, the second emission layer 2452 may be located on the second electron blocking layer 2442, the second hole blocking layer 2462 may be located the second emission layer 2452, and the second electron transport layer 2472 may be disposed on the second hole blocking layer 2462.

The second electron transport layer 2472 may be disposed adjacent to the second emission layer 2452 and can transfer electrons to the second emission layer 2452.

The charge generation layer 249 may be disposed between the first electron transport layer 2471 and the second hole transport layer 2432 and can transfer electrons to the first electron transport layer 2471.

The first hole transport layer 2471 may be disposed adjacent to the first emission layer 2451 and can transfer holes to the first emission layer 2451.

Although FIG. 5B illustrates that each light emitting element includes two-stack structure, example embodiments of the present disclosure are not limited thereto. For example, each light emitting element may have other multi-stack structures such as a three-stack structure, a four-stack structure, and the like.

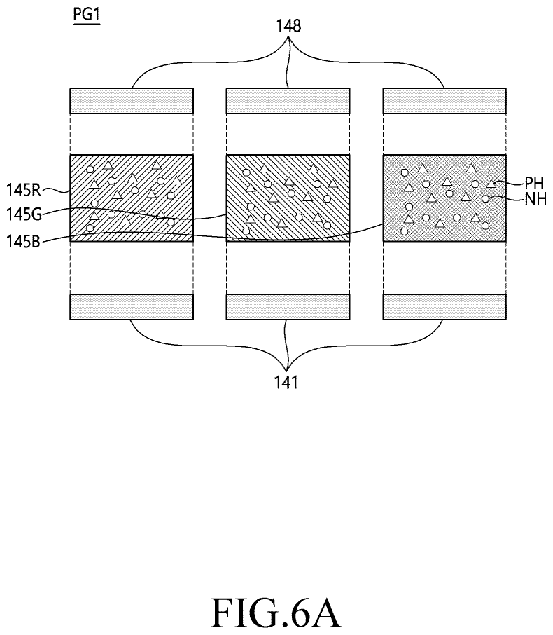

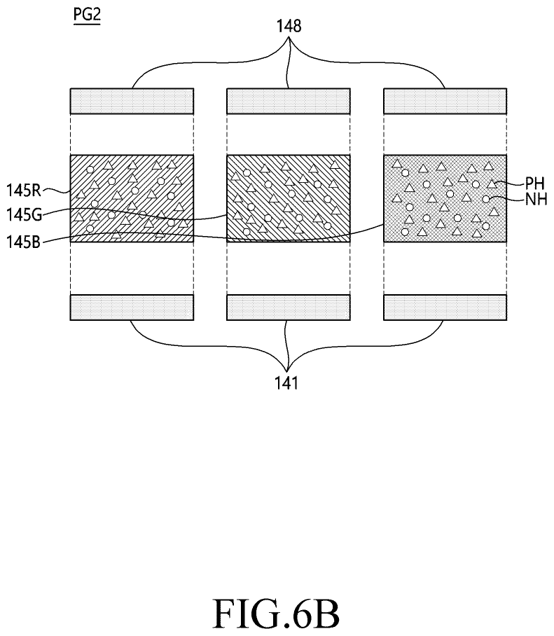

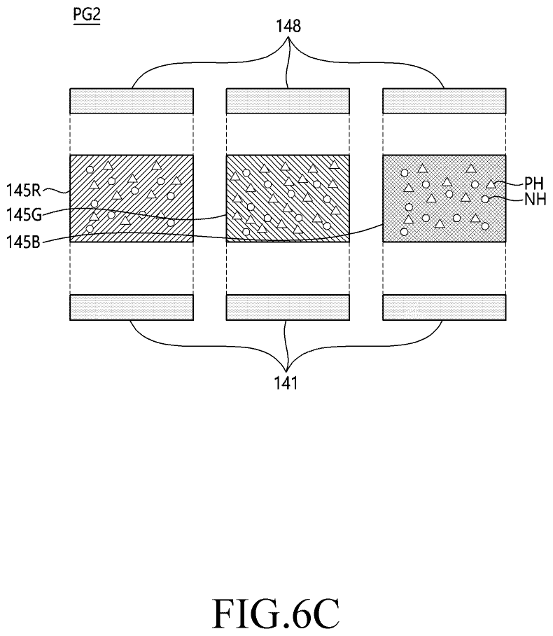

FIG. 6A is a cross-sectional view of example light emitting elements included in each first pixel PG1 (e.g., the first pixel PG1 of FIG. 3 described above) of the display device 100 according to aspects of the present disclosure.

Referring to FIG. 6A, each of light emitting elements included in each first pixel PG1 may include a first electrode layer 141, a second electrode layer 148, and an emission layer 145 that is located between the first electrode layer 141 and the second electrode layer 148, and is one of a red emission layer 145R, a green emission layer 145G, and a blue emission layer 145B.

The emission layer 145 may include at least one of a p-type host PH and an n-type host NH.

In one or more aspects, the emission layer 145 may further include a phosphorescent dopant (not shown) in addition to the p-type host PH and the n-type host NH.

Herein, the term “p-type host” may refer to a host material with a p-type property.

The p-type property may refer to the property of injecting or transporting holes at a highest occupied molecular orbital (HOMO) energy level, that is, the property of a material with high hole conductivity.

Herein, the term “n-type host” may refer to a host material with an n-type property.

The n-type property may refer to the property of injecting or transporting electrons at a lowest unoccupied molecular orbital (LUMO) energy level, that is, the property of a material with high electron conductivity.

A charge balance between holes and electrons can be adjusted by adjusting a ratio between the p-type host PH, the n-type host NH, and the phosphorescent dopant (not shown) included in the emission layer 145.

Thus, by controlling the charge balance, the lifetime of light emitting elements can be improved by optimizing the location of a recombination zone.

FIGS. 6B and 6C are cross-sectional views of example light emitting elements included in each second pixel PG2 (e.g., the second pixel PG2 of FIG. 4 described above) in the display device according to aspects of the present disclosure.

Referring to FIG. 6B, each of light emitting elements included in each second pixel PG2 may include a first electrode layer 141, a second electrode layer 148, and an emission layer 145 that is located between the first electrode layer 141 and the second electrode layer 148, and is one of a red emission layer 145R, a green emission layer 145G, and a blue emission layer 145B.

The emission layer 145 may include at least one of a p-type host PH and an n-type host NH.

In one or more aspects, the emission layer 145 may further include a phosphorescent dopant (not shown) in addition to the p-type host PH and the n-type host NH.

Referring to FIG. 6B, emission layers (145R, 145G, and 145B) included in each second pixel PG2 may have a p-type host (PH) ratio higher than the emission layers (145R, 145G, and 145B) of each first pixel PG1 in FIG. 6A described above.

For example, the emission layer 145 can satisfy the following equation:

$${p}_{1} / ( {n}_{1} + {p}_{1} ) < {p}_{2} / ( {n}_{2} + {p}_{2} ) \qquad Equation 1$$

where, p₁ is the number of moles of the p-type host of the emission layer 145 located in the first active area AA1, p₂ is the number of moles of the p-type host of the emission layer 145 located in the second active area AA2, mi is the number of moles of the n-type host of the emission layer 145 located in the first active area AA1, and n₂ is the number of moles of the n-type host of the emission layer 145 located in the second active area AA2.

In the display device 100, when emission layers 145 satisfies Equation 1, a recombination zone in the second active area AA2, compared to the first active area AA1, can be shifted about the emission layers 145, and thereby, mobility of holes, compared to electrons, can be increased, this leading the lifetime of corresponding light emitting elements to increase.

Accordingly, as the lifetime of light emitting elements in the second active area AA2 increases, even when driven for a long time, the display device 100 can provide an advantage of reducing a difference in luminance between an area where low-resolution second pixels PG2 are disposed and an area where high-resolution first pixels PG1 are disposed.

Referring to FIG. 6C, a green emission layer 145G included in each second pixel PG2 may have a p-type host (PH) ratio higher than the green emission layer 145G of each first pixel PG1 in FIG. 6A described above.

Further, a red emission layer 145R and a blue emission layer 145B included in each second pixel PG2 may have substantially the same p-type host (PH) ratio as the red emission layer 145R and the blue emission layer 145B included in each first pixel PG1 in FIG. 6A described above.

Herein, substantially the same may mean a degree of being considered as being equivalent to each other taking into account minute differences due to errors in the process of manufacturing the display panel 110 or display device 100.

For example, the green emission layer 145G may satisfy Equation 1 described above, and the red emission layer 145R and the blue emission layer 145B may satisfy following equation:

$${p}_{1} / ( {n}_{1} + {p}_{1} ) = {p}_{2} / ( {n}_{2} + {p}_{2} ) \qquad Equation 2$$

where, p₁ is the number of moles of the p-type host of the emission layer 145 located in the first active area AA1, p₂ is the number of moles of the p-type host of the emission layer 145 located in the second active area AA2, n₁ is the number of moles of the n-type host of the emission layer 145 located in the first active area AA1, and n₂ is the number of moles of the n-type host of the emission layer 145 located in the second active area AA2.

In the display device 100, when green emission layers 145G satisfy Equation 1, a recombination zone in the second active area AA2, compared to the first active area AA1, can be shifted about the green emission layers 145G, and thereby, mobility of holes, compared to electrons, can be increased, this leading the lifetime of corresponding light emitting elements to increase.

Since the ratio of the luminance of light emitted by the green emission layers 145G to the total luminance of the display device 100 is 70% or more, a main factor in determining the lifetime of light emitting elements included in the second active area AA2 may be the green emission layers 145G.

Therefore, increasing the ratio of the p-type host PH of the green emission layers 145G may be desirable to increase the lifetime of the light emitting elements included in the second active area AA2.

However, example embodiments of the present disclosure for increasing a ratio of the p-type host PH are not limited to the green emission layers 145G. For example, a type and/or amount of p-type host PH can be adjusted depending on a difference in acceleration coefficients of red subpixels R, green subpixels G, and blue subpixels B.

For example, since the acceleration coefficient of red subpixels R is greater than those of green subpixels G and blue subpixels B, an amount of the p-type host PH in red emission layers 145R of the first active area AA1 may be different an amount of the p-type host PH in red emission layers 145R of the second active areas AA2.

Therefore, in some examples, increasing the ratio of the p-type host PH of the red emission layers 145R may be desirable to increase the lifetime of the light emitting elements included in the second active area AA2.

Referring to FIGS. 6A and 6B, a p-type host PH, which is further added to increase a ratio of the p-type host included in the emission layers (145R, 145G, 145B) located in the second active area AA2 of FIG. 6B, may be different from the p-type host PH included in the emission layers (145R, 145G, 145B) located in the first active area AA1, but example embodiments of the present disclosure are not limited thereto.

Likewise, a p-type host PH, which is further added to increase a ratio of the p-type host included in the green emission layer 145G located in the second active area AA2 of FIG. 6C, may be different from the p-type host PH included in the green emission layer 145G located in the first active area AA1, but example embodiments of the present disclosure are not limited thereto.

For example, the display device 100 can satisfy Equation 1 and at the same time, satisfy the following equation:

$${p}_{2} = k * {p}_{1} + m * {p}_{0} \qquad Equation 3$$

where, k is an arbitrary constant equal to or greater than 1, m is an arbitrary constant equal to or greater than 0, p₀ is the number of moles of a p-type host different from the p-type host of the emission layer in the first active area AA1, p₁ is the number of moles of the p-type host of the emission layer 145 located in the first active area AA1, and p₂ is the number of moles of the p-type host of the emission layer 145 located in the second active area AA2.

In Equation 3, when k is greater than 1 and m equals to 0, p₂=k*p₁ is satisfied, and therefore, the p-type host PH further added to increase the ratio of the p-type host included in the emission layers (145R, 145G, 145B) located in the second active area AA2 may be substantially the same as the p-type host PH of the emission layers (145R, 145G, 145B) located in the first active area AA1.

Likewise, when k is greater than 1 and m equals to 0, p₂=k*p₁ is satisfied, and therefore, the p-type host PH further added to increase the ratio of the p-type host included in the green emission layers 145G located in the second active area AA2 may be substantially the same as the p-type host PH of the green emission layers 145G located in the first active area AA1.

In Equation 3, when k equals to 1 and m is greater than 0, p₂=p₁+m*p₀ is satisfied, and therefore, the p-type host PH further added to increase the ratio of the p-type host included in the emission layers (145R, 145G, 145B) located in the second active area AA2 may be different from the p-type host PH of the emission layers (145R, 145G, 145B) located in the first active area AA1.

Likewise, when k equals to 1 and m is greater than 0, p₂=p₁+m*p₀ is satisfied, and therefore, the p-type host PH further added to increase the ratio of the p-type host included in the green emission layers 145G located in the second active area AA2 may be different from the p-type host PH of the green emission layers 145G located in the first active area AA1.

Therefore, the p-type host added to increase the p-type host ratio may be the same as or different from the p-type host already included before the p-type host is added to increase the p-type host ratio. As described later, this can be realized by enabling a type and/or amount of the p-type host to be adjusted using a thin film deposition apparatus 300 for manufacturing light emitting elements.

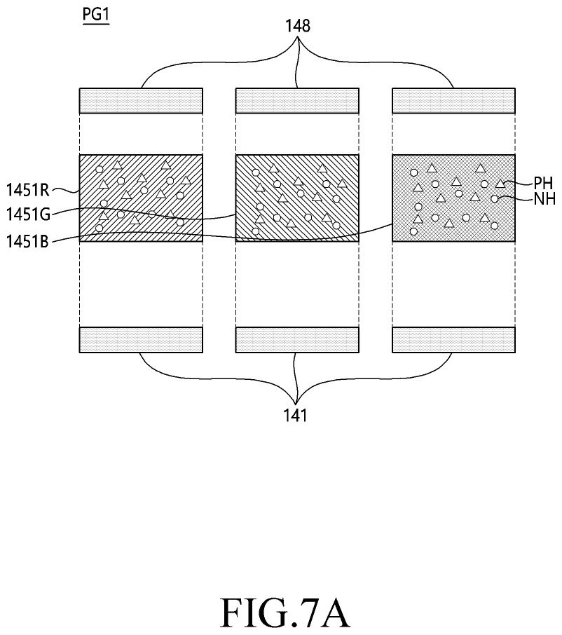

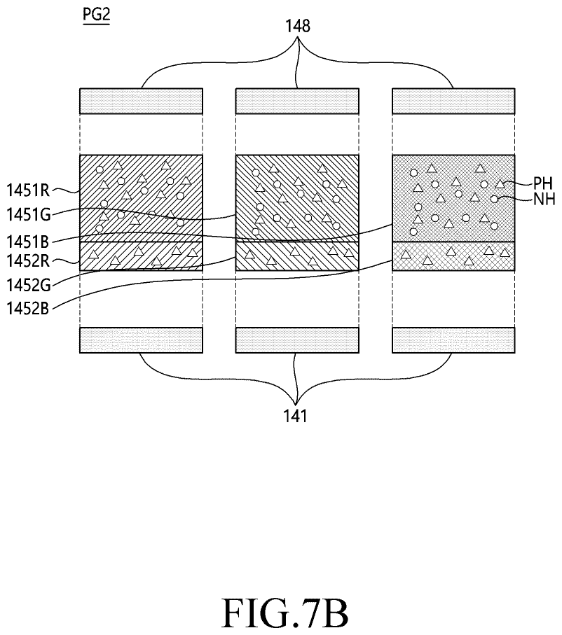

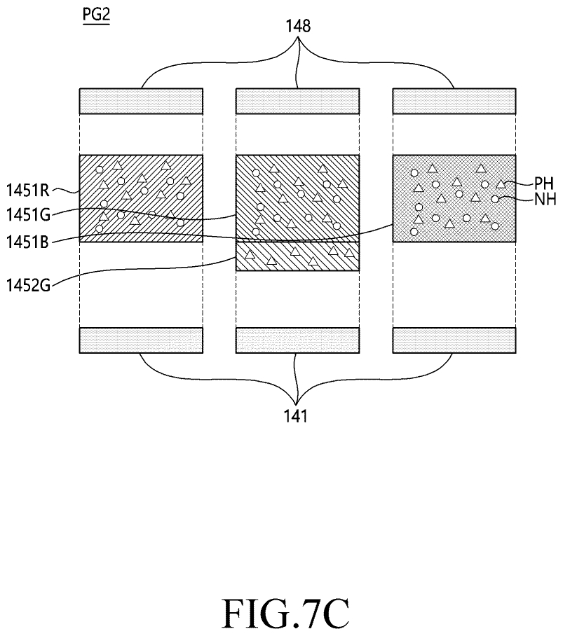

FIG. 7A is another cross-sectional view of example light emitting elements included in a first pixel (e.g., the first pixel PG1 of FIG. 3 described above) of the display device 100 according to aspects of the present disclosure.

Referring to FIG. 7A, each of light emitting elements included in each first pixel PG1 may include a first electrode layer 141, a second electrode layer 148, and an emission layer 145 that is located between the first electrode layer 141 and the second electrode layer 148, and is one of a red emission layer 145R, a green emission layer 145G, and a blue emission layer 145B.

Further, the red emission layer 145R, the green emission layer 145G, and the blue emission layer 145B may respectively include first layers (1451R, 1451G, and 1451B) including a p-type host PH and an n-type host NH.

In one or more aspects, the emission layers 145 may further include a phosphorescent dopant (not shown) in addition to the p-type host PH and the n-type host NH.

FIGS. 7B and 7C are other cross-sectional views of example light emitting elements included in each second pixel PG2 (e.g., the second pixel PG2 of FIG. 4 described above) the display device according to aspects of the present disclosure.

Referring to FIG. 7B, each of light emitting elements included in each second pixel PG2 may include a first electrode layer 141, a second electrode layer 148, and an emission layer 145 that is located between the first electrode layer 141 and the second electrode layer 148, and is one of a red emission layer 145R, a green emission layer 145G, and a blue emission layer 145B.

Further, each of the red emission layer 145R, the green emission layer 145G, and the blue emission layer 145B may include a respective first layer (1451R, 1451G, and 1451B) including a p-type host PH and an n-type host NH, and a respective second layer (1452R, 1452G, and 1452B) located on a surface of the first layer and including a p-type host.

In one or more aspects, when the first electrode layer 141 is an anode electrode, and the second electrode layer 148 is a cathode electrode, the second layer may be located between the first layer and the first electrode layer 141.

However, example embodiments of present disclosure are not limited thereto. For example, when the first electrode layer 141 is a cathode electrode, and the second electrode layer 148 is an anode electrode, the second layer may be located between the first layer and the second electrode layer 148.

Referring to FIGS. 7A and 7B, in the display device 100, when the second layers (1452R, 1452G, and 1452B) including the p-type host are deposited on the respective surfaces of the first layers (1451R, 1451G, and 1451B) including the p-type host and the n-type host, the entire ratio of the p-type host in the emission layers 145 can be increased.

Therefore, as the ratio of the p-type host in the emission layers 145 increases, a recombination zone in the second active area AA2, compared to the first active area AA1, can be shifted about the emission layers 145, and thereby, mobility of holes, compared to electrons, can be increased, this leading the lifetime of corresponding light emitting elements to increase.

Accordingly, as the lifetime of the light emitting elements in the second active area AA2 increases, even when driven for a long time, the display device 100 can provide an advantage of reducing a difference in luminance between an area where low-resolution second pixels PG2 are disposed and an area where high-resolution first pixels PG1 are disposed.

Referring to FIG. 7C, a green emission layer 145G may include a first layer 1451G including a p-type host PH and an n-type host NH, and a second layer 1452G located on a surface of the first layer and including a p-type host.

Further, each of a red emission layer 145R and a blue emission layer 145B may include a respective first layer (1451R and 1451B) including a p-type host PH and an n-type host NH. As shown, while the green emission layer 145G includes the second layer 1452G including the p-type host, adjacent blue emission layer 145B or red emission layer 145R do not have a second layer.

As the ratio of the p-type host is increased by the second layer 1452G of the green emission layer 145G, a recombination zone in the second active area AA2, compared to the first active area AA1, can be shifted about the green emission layer 145G, and thereby, mobility of holes, compared to electrons, can be increased, this leading the lifetime of a corresponding light emitting element to increase.

Since the ratio of the luminance of light emitted by the green emission layers 145G to the total luminance of the display device 100 is 70% or more, a main factor in determining the lifetime of light emitting elements included in the second active area AA2 may be the green emission layers 145G.

Accordingly, as the ratio of the p-type host of the green emission layers 145G is increased, the lifetime of the light emitting elements in the second active area AA2 can be increased, and even when driven for a long time, the display device 100 can provide an advantage of reducing a difference in luminance between an area where low-resolution second pixels PG2 are disposed and an area where high-resolution first pixels PG1 are disposed.

Referring to FIGS. 7A and 7B, the second layers (1452R, 1452G, and 1452B) including the p-type host PH may be deposited on the respective surfaces of the first layers (1451R, 1451G, and 1451B) to increase a ratio of the p-type host PH included in the emission layers (145R, 145G, and 145B) located in the second active area AA2 of FIG. 7B, and in this implementation, the p-type host PH of the first layers (1451R, 1451G, and 1451B) may be different from the p-type host PH of the second layers (1452R, 1452G, and 1452B). However, example embodiments of the present disclosure are not limited thereto.

Likewise, the second layer 1452G including the p-type host PH may be deposited on the surface of the first layer 1451G to increase a ratio of the p-type host PH included in the green emission layer 145G located in the second active area AA2 of FIG. 7C, and in this implementation, the p-type host PH of the first layer 1451G may be different from the p-type host PH of the second layer 1452G. However, example embodiments of the present disclosure are not limited thereto.

Therefore, to increase the ratio of the p-type host, the p-type host included in the second layers may be the same as or different from the p-type host included in the first layer. As described below, this can be realized by enabling a type and/or amount of the p-type host PH of the second layer to be adjusted using a thin film deposition apparatus 300.

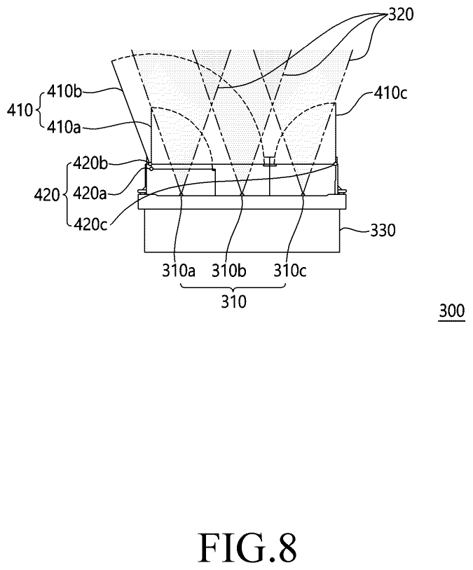

FIG. 8 is a front view of an example thin film deposition apparatus used for manufacturing light emitting elements according to aspects of the present disclosure.

Referring to FIG. 8, the thin film deposition apparatus 300 for manufacturing light emitting elements may include a source unit 330 with spray nozzles 310 configured to spray deposition materials 320 to provide the deposition materials 320.

Referring to FIG. 8, the thin film deposition apparatus 300 for manufacturing light emitting elements may include a first rotation axis 420a and a second rotation axis 420b, which are disposed close to each other. The first rotation axis 420a and the second rotation axis 420b can open or close respective spray nozzles 310 while rotating in a same direction.

In addition, the thin film deposition apparatus 300 may further include a third rotation axis 420c and a third cover 410c connected to the third rotation axis 420c. The third cover 410c can open or close a spray nozzle 310 while rotating in a direction opposite to a rotation direction of the first rotation axis 420a and the second rotation axis 420b.

Even when the first rotation axis 420a and the second rotation axis 420b are disposed to be spaced apart from each other and rotate in a same direction, the deposition materials 320 may not be deposited on a second cover 410b depending on a length of a first cove 410a or the second cover 410b and a spray angle of the spray nozzles 310. In this situation, the first rotation axis 420a and the second rotation axis 420b may be disposed to be spaced apart from each other, and thereafter, can rotate in a same direction.

In one or more aspects, the first cover 410a may have a length enough to close a first spray nozzle 310a to open or close the first spray nozzle 310a. In one or more aspects, the second cover 410b may be required to open or close a second spray nozzle 310b disposed on a side of the first spray nozzle 310a, and therefore, the second cover 410b may have a length enough to close both the first spray nozzle 310a and the second spray nozzle 310b.

For example, in a situation where the second rotation axis 420b is disposed close to the first rotation axis 420a, the second cover 410b may close the second spray nozzle 310b by the rotation of the second cover 410b and the first cover 410a in a same direction.

Referring to FIG. 8, the second cover 410b may be opened with a larger angle than the first cover 410a.

In this implementation, even when the deposition materials 320 are sprayed through the spray nozzles 310, the deposition materials 320 may not contact the second cover 410b, and thus, the deposition material 320 can be prevented from being deposited on the second cover 410b.

Further, the first cover 410a can prevent the deposition material 320 from being deposited on the first cover 410a through a change in an opening angle of the first cover 410a depending on a spray angle of the deposition material 320.

In one or more aspects, a plurality of deposition materials 320 and a plurality of spray nozzles 310 may be provided. For example, two or more deposition materials 320 and two or more spray nozzles 310 may be provided in the thin film deposition apparatus 300.

As shown in FIG. 8, when three deposition materials 320 and three spray nozzles 310 are provided, the first cover 410a and the second cover 410b among the three covers 410 may rotate in a same direction, and the third cover 410c may rotate in an opposite direction.

By selectively opening the three covers 410, the deposition may be selectively performed for each of the deposition material 320 sprayed from the first spray nozzle 310a, the deposition material 320 sprayed from the second spray nozzle 310b, and the deposition materials 320 sprayed from the third spray nozzle 310c.

For example, the deposition material 320 sprayed from the first spray nozzle 310a may be a p-type host material, the deposition material 320 sprayed from the second spray nozzle 310b may be a phosphorescent dopant, and the deposition material 320 sprayed from the third spray nozzle 310c may be a mixture of the p-type host and an n-type host.

In this example, the p-type host sprayed from the first spray nozzle 310a and the p-type host sprayed from the third spray nozzle 310c may be the same or different.

In this implementation, as described above, the covers 410 of the thin film deposition apparatus 300 for manufacturing light emitting elements may be manipulated such that the display device 100 can satisfy Equation 1 as follows:

$${p}_{1} / ( {n}_{1} + {p}_{1} ) < {p}_{2} / ( {n}_{2} + {p}_{2} ) \qquad Equation 1$$

where, p₁ is the number of moles of the p-type host of an emission layer 145 (e.g., the emission layer 145 in the figures discussed above) located in a first active area AA1 (e.g., the first active area AA1 of FIG. 3 described above), p₂ is the number of moles of the p-type host of an emission layer 145 (e.g., the emission layer 145 in the figures discussed above) located in a second active area AA2 (e.g., the second active area AA2 of FIG. 4 described above), n₁ is the number of moles of the n-type host of the emission layer 145 located in the first active area AA1, and n₂ is the number of moles of the n-type host of the emission layer 145 located in the second active area AA2.

In one example, when forming an emission layer 145 located in the first active area AA1, the first cover 410a may be rotated clockwise to close the first spray nozzle 310a, and the second cover 410b and the third cover 410c may be opened to open the spray nozzle 310b and the third spray nozzle 310c.

Therefore, the first spray nozzle 310a may be closed, and the second spray nozzle 310b and the third spray nozzle 310c may be opened. Thereby, the emission layer 145 may be formed that includes the phosphorescent dopant, which is the deposition material 320 sprayed from the second spray nozzle 310b, and a mixture of the p-type host and the n-type host, which is the deposition material 320 sprayed from the third spray nozzle 310c.

In one example, when forming an emission layer 145 located in the second active area AA2, the first cover 410a, the second cover 410b, and the third cover 410c can be opened to open the first spray nozzle 310a, the second spray nozzle 310b, and the third spray nozzle 310c.

Therefore, the first spray nozzle 310a, the second spray nozzle 310b, and the third spray nozzle 310c may be opened. Thereby, the p-type host ratio of the emission layer 145 located in the second active area AA2 can be increased by the additional deposition of the p-type host, which is the deposition material 320 sprayed from the first spray nozzle 310a, as well as the phosphorescent dopant, which is the deposition material 320 sprayed from the second spray nozzle 310b, and a mixture of the p-type host and the n-type host, which is the deposition material 320 sprayed from the third spray nozzle 310c.

This emission layer 145 may be, for example, a green emission layer 145G.

In another example, the deposition material 320 sprayed from the first spray nozzle 310a may be a mixture of a p-type host and an n-type host, the deposition material 320 sprayed from the second spray nozzle 310b may be a phosphorescent dopant, and the deposition material 320 sprayed from the third spray nozzle 310c may be a p-type host.

In this example, the p-type host sprayed from the first spray nozzle 310a and the p-type host sprayed from the third spray nozzle 310c may be the same or different.

In this implementation, as described above, in the stage of forming the first layers (1451R, 1451G, and 1451B) including the p-type host and the n-type host, the third cover 410c may be rotated counterclockwise to close the third spray nozzle 310c, and the first cover 410a and the second cover 410b may be opened to open the first spray nozzle 310a and the second spray nozzle 310b.

Accordingly, the first layers (1451R, 1451G, and 1451B) may include the p-type host and the n-type host.

Further, in the stage of forming the second layers (1452R, 1452G, and 1452B) including the p-type host, the first cover 410a may be rotated clockwise to close the first spray nozzle 310a, and the second cover 410b and the third cover 410c may be opened to open the second spray nozzle 310b and the third spray nozzle 310c.

Accordingly, the second layers (1452R, 1452G, and 1452B) may include the p-type host.

In this implementation, the first layer and the second layer may be, for example, the first layer 1451G and the second layer 1452G of the green emission layer 145G.

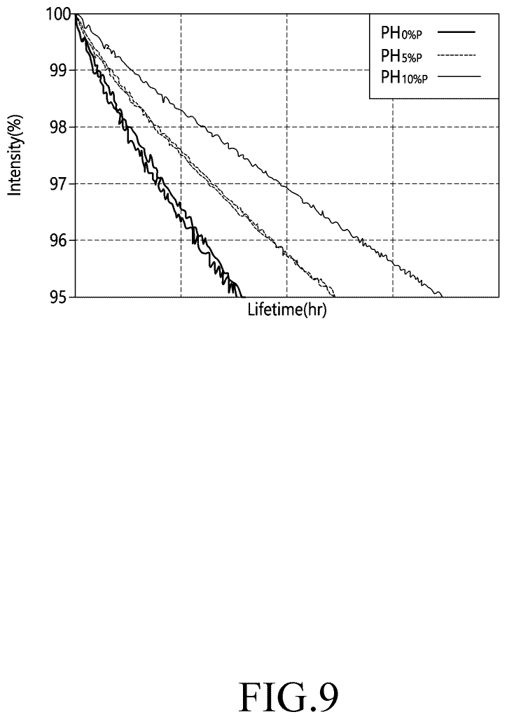

FIG. 9 is a graph showing the lifetime and intensity of a green subpixel with respect to p-type host ratios in the display device 100 according to aspects of the present disclosure.

The following Table 1 shows the experimental results corresponding to the graph in FIG. 9.

TABLE 1

| p-type | Threshold | Driving voltage | Efficiency | Lifetime |
|---|---|---|---|---|
| host ratio | voltage (V) | (V) | (%) | (%) |
| PH_{0%P} | 0.0 | 0.0 | 100.0 | 100.0 |
| PH_{5%P} | −0.02 | 0.0 | 99.6 | 158.4 |
| PH_{10%P} | −0.05 | 0.0 | 99.1 | 223.4 |

Referring to FIG. 9 and Table 1, when a p-type host ratio (p/(n+p)) increases by 5% P (PH_{5%P}) or 10% P (PH_{10%P}) compared to a comparative example (PH_{0%P}) to which examples of the present disclosure are not applied, it can be seen that time (lifetime) taken to reach the intensity of 95% increases.

In other words, as the p-type host ratio increases, the lifetime can increase.

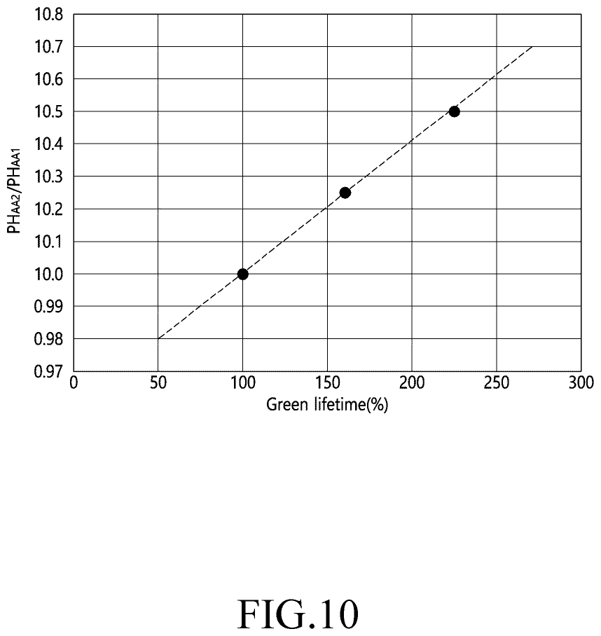

FIG. 10 is a graph showing the lifetime of a green subpixel with respect to a p-type host molar ratio (PH_{AA2}/PH_{AA1}) of a second active area AA2 (e.g., the second active area AA2 of FIG. 4 described above) to a first active area AA1 (e.g., the first active area AA1 of FIG. 3 described above) in the display device 100 according to aspects of the present disclosure.

Referring to FIG. 10, as the p-type host molar ratio (PH_{AA2}/PH_{AA1}) of the second active area AA2 to the first active area AA1 increases, it can be seen that the lifetime of a green subpixel increases.

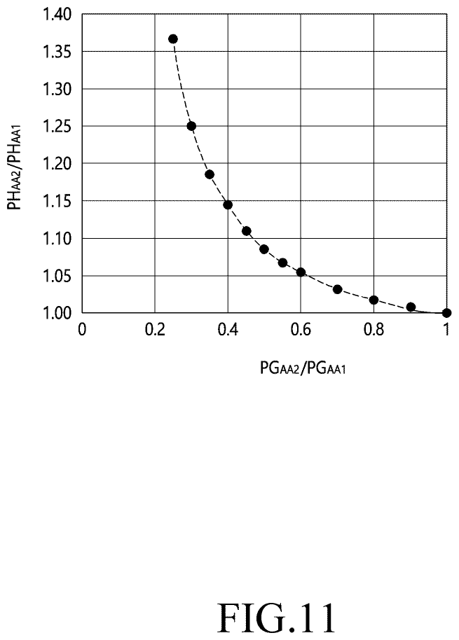

FIG. 11 is a graph showing a pixel area ratio (PG_{AA2}/PG_{AA1}) of a second active area AA2 (e.g., the second active area AA2 of FIG. 4 described above) to a first active area AA1 (e.g., the first active area AA1 of FIG. 3 described above) with respect to a p-type host molar ratio (PH_{AA2}/PH_{AA1}) of the second active area AA2 to the first active area AA1 in the display device 100 according to aspects of the present disclosure.

Referring to FIG. 11, as the p-type host molar ratio (PH_{AA2}/PH_{AA1}) of the second active area AA2 to the first active area AA1 increases, it can be seen that the pixel area ratio (PG_{AA2}/PG_{AA1}) of the second active area AA2 to the first active area AA1 decreases.

However, as described above, this is not limited to the green subpixel. For example, as shown in Table 2, in even a red subpixel and a blue subpixel, as the p-type host molar ratio (PH_{AA2}/PH_{AA1}) of the second active area AA2 to the first active area AA1 increases, the lifetime of the red and blue subpixels can increase.

TABLE 2

| | PG_{AA2}/ | C_{AA2}/ | L_{AA2} | RQL_{AA2} | PH_{AA2}/ |
|---|---|---|---|---|---|
| | PG_{AA1} | C_{AA1} | (%) | (%) | PH_{AA1} |
| Red | 1.00 | 1.00 | 100 | 100 | 1.00 |
| subpixel | 0.90 | 1.11 | 83 | 120 | 1.01 |
| | 0.80 | 1.25 | 67 | 149 | 1.02 |
| | 0.70 | 1.43 | 52 | 192 | 1.04 |
| | 0.60 | 1.67 | 39 | 256 | 1.06 |
| | 0.55 | 1.82 | 34 | 294 | 1.08 |
| | 0.50 | 2.00 | 28 | 357 | 1.10 |
| | 0.45 | 2.22 | 23 | 435 | 1.14 |
| | 0.40 | 2.25 | 19 | 526 | 1.17 |
| | 0.35 | 2.86 | 15 | 667 | 1.23 |
| | 0.30 | 3.33 | 11 | 909 | 1.33 |
| | 0.25 | 4.00 | 8 | 1250 | 1.47 |
| Green | 1.00 | 1.00 | 100 | 100 | 1.00 |
| subpixel | 0.90 | 1.11 | 84 | 119 | 1.01 |
| | 0.80 | 1.25 | 69 | 145 | 1.02 |
| | 0.70 | 1.43 | 56 | 179 | 1.03 |
| | 0.60 | 1.67 | 43 | 233 | 1.05 |
| | 0.55 | 1.82 | 38 | 263 | 1.07 |
| | 0.50 | 2.00 | 32 | 313 | 1.09 |
| | 0.45 | 2.22 | 27 | 370 | 1.11 |
| | 0.40 | 2.25 | 22 | 455 | 1.14 |
| | 0.35 | 2.86 | 18 | 556 | 1.19 |
| | 0.30 | 3.33 | 14 | 714 | 1.25 |
| | 0.25 | 4.00 | 10 | 1000 | 1.37 |
| Blue | 1.00 | 1.00 | 100 | 100 | 1.00 |
| subpixel | 0.90 | 1.11 | 84 | 119 | 1.01 |
| | 0.80 | 1.25 | 69 | 145 | 1.02 |
| | 0.70 | 1.43 | 56 | 179 | 1.03 |
| | 0.60 | 1.67 | 43 | 233 | 1.05 |
| | 0.55 | 1.82 | 38 | 263 | 1.07 |
| | 0.50 | 2.00 | 32 | 313 | 1.09 |
| | 0.45 | 2.22 | 27 | 370 | 1.11 |
| | 0.40 | 2.25 | 22 | 455 | 1.14 |
| | 0.35 | 2.86 | 18 | 556 | 1.19 |
| | 0.30 | 3.33 | 14 | 714 | 1.25 |
| | 0.25 | 4.00 | 10 | 1000 | 1.37 |

Referring to Table 2, a p-type host ratio may be different to reduce a difference in lifetime between the first active area AA1 and the second active area AA2 due to a difference in acceleration coefficients between red, green, and blue subpixels.

For example, in the green subpixel, when a pixel area ratio (PG_{AA2}/PG_{AA1}) of the second active area AA2 to the first active area AA1 is 0.5, a current ratio (C_{AA2}/C_{AA1}) of the second active area AA2 to the first active area AA1 can become 2, and the lifetime L_{AA2} of the second active area AA2 can decrease to 32% compared to a situation where the pixel area ratio (PG_{AA2}/PG_{AA1}) of the second active area AA2 to the first active area AA1 is 1.

Accordingly, lifetime (RQL_{AA2}) required to reduce a difference between the first active area AA1 and the second active area AA2 can increase to 313% compared to a situation where the pixel area ratio (PG_{AA2}/PG_{AA1}) of the second active area AA2 to the first active area AA1 is 1.

Therefore, to compensate for the required lifetime, the p-type host can be further deposited so that the p-type host molar ratio (PH_{AA2}/PH_{AA1}) of the second active area AA2 to the first active area AA1 can be 1.09.

The example embodiments described above will be briefly described as follows.

According to the example embodiments described herein, a display device can be provided that includes: a first active area in which a plurality of first pixels are disposed, the first active area having a first resolution; a second active area in which a plurality of second pixels are disposed, the second active area having a second resolution less than the first resolution; and a plurality of light emitting elements disposed in each of the plurality of first pixels and the plurality of second pixels. Each of the plurality of light emitting elements may include a first electrode layer, a second electrode layer, and an emission that is located between the first electrode layer and the second electrode layer and is any one of a red emission layer, a green emission layer, and a blue emission layer. The emission layer may include at least one of a p-type host and an n-type host, and at least one of the red emission layer, the green emission layer, and the blue emission layer may be configured to satisfy the following equation:

$${p}_{1} / ( {n}_{1} + {p}_{1} ) < {p}_{2} / ( {n}_{2} + {p}_{2} ) \qquad Equation 1$$

where, p₁ may be the number of moles of the p-type host of the emission layer located in the first active area, p₂ may be the number of moles of the p-type host of the emission layer located in the second active area, n₁ may be the number of moles of the n-type host of the emission layer located in the first active area, and n₂ may be the number of moles of the n-type host of the emission layer located in the second active area.

In one or more aspects, the green emission layer may be configured to satisfy Equation 1, and the red emission layer and the blue emission layer may be configured to satisfy the following equation:

$${p}_{1} / ( {n}_{1} + {p}_{1} ) = {p}_{2} / ( {n}_{2} + {p}_{2} ) \qquad Equation 2$$

where, p₁ may be the number of moles of the p-type host of the emission layer located in the first active area, p₂ may be the number of moles of the p-type host of the emission layer located in the second active area, n₁ may be the number of moles of the n-type host of the emission layer located in the first active area, and n₂ may be the number of moles of the n-type host of the emission layer located in the second active area.

In one or more aspects, at least one of the red emission layer, the green emission layer, and the blue emission layer may be configured to satisfy the following equations:

$${p}_{1} / ( {n}_{1} + {p}_{1} ) < {p}_{2} / ( {n}_{2} + {p}_{2} ) \qquad Equation 1$$

$${p}_{2} = k * {p}_{1} + m * {p}_{0} \qquad Equation 3$$

where, k may be an arbitrary constant equal to or greater than 1, m may be an arbitrary constant equal to or greater than 0, p₀ may be the number of moles of a p-type host different from the p-type host of the emission layer in the first active area, p₁ may be the number of moles of the p-type host of the emission layer located in the first active area, p₂ may be the number of moles of the p-type host of the emission layer located in the second active area, n₁ may be the number of moles of the n-type host of the emission layer located in the first active area, and n₂ may be the number of moles of the n-type host of the emission layer located in the second active area.

In one or more aspects, the k may be greater than 1, and the m may equal to 0.

In one or more aspects, the k may equal to 1, and the m may be greater than 0.

In one or more aspects, the emission layer may further include a phosphorescent dopant.

According to the example embodiments described herein, a display device can be provided that includes: a first active area in which a plurality of first pixels are disposed, the first active area having a first resolution; a second active area in which a plurality of second pixels are disposed, the second active area having a second resolution less than the first resolution; and a plurality of light emitting elements disposed in each of the plurality of first pixels and the plurality of second pixels. Each of the plurality of light emitting elements may include a first electrode layer, a second electrode layer, and an emission that is located between the first electrode layer and the second electrode layer and is any one of a red emission layer, a green emission layer, and a blue emission layer. The emission layer may include at least one of a p-type host and an n-type host. At least one of the red emission layer, the green emission layer, and the blue emission layer, which are located in the second active area, may include a first layer including the p-type host and the n-type host, and a second layer located on a surface of the first layer and including the p-type host. At least one of the red emission layer, the green emission layer, and the blue emission layer, which are located in the first active area, may include a first layer including the p-type host and the n-type host.

In one or more aspects, the green emission layer located in the second active area may include the first layer including the p-type host and the n-type host, and the second layer located on the first layer and including the p-type host, and the green emission layer located in the first active area may include the first layer including the p-type host and the n-type host.

In one or more aspects, the p-type host of the first layer and the p-type host of the second layer may be the same as each other.

In one or more aspects, the p-type host of the first layer and the p-type host of the second layer may be different from each other.

In one or more aspects, the first electrode layer may be an anode electrode, the second electrode layer may be a cathode electrode, and the second layer may be located between the first layer and the second electrode layer.

In one or more aspects, the emission layer may further include a phosphorescent dopant.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the scope of the technical features of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a first active area in which a plurality of first pixels is disposed, the first active area having a first resolution;
a second active area in which a plurality of second pixels is disposed, the second active area having a second resolution less than the first resolution; and
a plurality of light emitting elements disposed in each of the plurality of first pixels and the plurality of second pixels,
wherein each of the plurality of light emitting elements comprises a first electrode layer, a second electrode layer, and an emission layer that is located between the first electrode layer and the second electrode layer and is any one of a red emission layer, a green emission layer, and a blue emission layer, and
wherein the emission layer comprises at least one of a p-type host and an n-type host, and at least one of the red emission layer, the green emission layer, and the blue emission layer is configured to satisfy the following equation:
$${p}_{1} / ( {n}_{1} + {p}_{1} ) < {p}_{2} / ( {n}_{2} + {p}_{2} ) \qquad Equation 1$$
where:
p₁ is a number of moles of the p-type host of the emission layer located in the first active area;
p₂ is a number of moles of the p-type host of the emission layer located in the second active area;
n₁ is a number of moles of the n-type host of the emission layer located in the first active area; and
n₂ is a number of moles of the n-type host of the emission layer located in the second active area.

2. The display device of claim 1, wherein the green emission layer is configured to satisfy Equation 1, and the red emission layer and the blue emission layer are configured to satisfy the following equation:
$${p}_{1} / ( {n}_{1} + {p}_{1} ) = {p}_{2} / ( {n}_{2} + {p}_{2} ) \qquad Equation 2$$
where:
p₁ is the number of moles of the p-type host of the emission layer located in the first active area;
p₂ is the number of moles of the p-type host of the emission layer located in the second active area;
n₁ is the number of moles of the n-type host of the emission layer located in the first active area; and
n₂ is the number of moles of the n-type host of the emission layer located in the second active area.

3. The display device of claim 1, wherein at least one of the red emission layer, the green emission layer, and the blue emission layer is configured to satisfy the following equations:
$${p}_{1} / ( {n}_{1} + {p}_{1} ) < {p}_{2} / ( {n}_{2} + {p}_{2} ) \qquad Equation 1$$
$${p}_{2} = k * {p}_{1} + m * {p}_{0} \qquad Equation 3$$
where:
k is an arbitrary constant equal to or greater than 1;
m is an arbitrary constant equal to or greater than 0;
p₀ is a number of moles of a p-type host different from the p-type host of the emission layer located in the first active area;
p₁ is the number of moles of the p-type host of the emission layer located in the first active area;
p₂ is the number of moles of the p-type host of the emission layer located in the second active area;
n₁ is the number of moles of the n-type host of the emission layer located in the first active area; and
n₂ is the number of moles of the n-type host of the emission layer located in the second active area.

4. The display device of claim 3, wherein the k is greater than 1, and the m equals to 0.

5. The display device of claim 3, wherein the k equals to 1, and the m is greater than 0.

6. The display device of claim 1, wherein the emission layer further comprises a phosphorescent dopant.

7. A display device comprising:
a first active area in which a plurality of first pixels is disposed, the first active area having a first resolution;
a second active area in which a plurality of second pixels is disposed, the second active area having a second resolution less than the first resolution; and
a plurality of light emitting elements disposed in each of the plurality of first pixels and the plurality of second pixels,
wherein each of the plurality of light emitting elements comprises a first electrode layer, a second electrode layer, and an emission layer that is located between the first electrode layer and the second electrode layer and is any one of a red emission layer, a green emission layer, and a blue emission layer,
wherein the emission layer comprises at least one of a p-type host and an n-type host,
wherein at least one of the red emission layer, the green emission layer, and the blue emission layer, which are located in the second active area, comprises a first layer comprising the p-type host and the n-type host, and a second layer located on the first layer and including the p-type host, and
wherein at least one of the red emission layer, the green emission layer, and the blue emission layer, which are located in the first active area, comprises a first layer including the p-type host and the n-type host.

8. The display device of claim 7, wherein the green emission layer located in the second active area comprises a first layer comprising the p-type host and the n-type host, and a second layer located on the first layer and comprising the p-type host, and
wherein the green emission layer located in the first active area comprises the first layer comprising the p-type host and the n-type host.

9. The display device of claim 7, wherein the p-type host of the first layer and the p-type host of the second layer are the same as each other.

10. The display device of claim 7, wherein the p-type host of the first layer and the p-type host of the second layer are different from each other.

11. The display device of claim 7, wherein the first electrode layer is an anode electrode, and the second electrode layer is a cathode electrode, and
wherein the second layer is located between the first layer and the first electrode layer.

12. The display device of claim 7, wherein the emission layer further comprises a phosphorescent dopant.

13. A display device comprising:
a first active area in which a plurality of first pixels is disposed;
a second active area in which a plurality of second pixels is disposed; and
a plurality of light emitting elements disposed in each of the plurality of first pixels and the plurality of second pixels, each light emitting element of the plurality of light emitting elements including:
a first electrode layer;
a second electrode layer; and
an emission layer between the first electrode layer and the second electrode layer, the emission layer having a first layer including at least one of a p-type host and an n-type host,
wherein the emission layer is any one of a red emission layer, a green emission layer, and a blue emission layer, and
wherein a density of the plurality of first pixels in the first active area is greater than a density of the plurality of second pixels in the second active area.

14. The display device of claim 13, wherein the emission layer includes a second layer adjacent to the first layer,
wherein the second layer includes the p-type host.

15. The display device of claim 14, wherein the second layer does not include the n-type host.

16. The display device of claim 14, wherein the emission layer is a green emission layer,
wherein p₁ is a number of moles of the p-type host of the emission layer located in the first active area;
wherein n₁ is a number of moles of the n-type host of the emission layer located in the first active area;
wherein p₂ is a number of moles of the p-type host of the emission layer located in the second active area;
wherein n₂ is a number of moles of the n-type host of the emission layer located in the second active area,
wherein a relationship of p₁, n₁, p₂, and n₂ is represented as p₁/(n₁+p₁)<p₂/(n₂+p₂).

17. The display device of claim 14, wherein the emission layer is either a blue emission layer or a red emission layer,
wherein p₁ is a number of moles of the p-type host of the emission layer located in the first active area;
wherein n₁ is a number of moles of the n-type host of the emission layer located in the first active area;
wherein p₂ is a number of moles of the p-type host of the emission layer located in the second active area;
wherein n₂ is a number of moles of the n-type host of the emission layer located in the second active area,
wherein a relationship of p₁, n₁, p₂, and n₂ is represented as p₁/(n₁+p₁)=p₂/(n₂+p₂).

18. The display device of claim 14, wherein p₁ is a number of moles of the p-type host of the emission layer located in the first active area;
wherein n₁ is a number of moles of the n-type host of the emission layer located in the first active area;
wherein p₂ is a number of moles of the p-type host of the emission layer located in the second active area;
wherein n₂ is a number of moles of the n-type host of the emission layer located in the second active area;
wherein a relationship of p₁, n₁, p₂, and n₂ is represented as p₁/(n₁+p₁)<p₂/(n₂+p₂);
wherein k is an arbitrary constant equal to or greater than 1;
wherein m is an arbitrary constant equal to or greater than 0;
wherein p₀ is a number of moles of a p-type host different from the p-type host of the emission layer located in the first active area; and
wherein a relationship of p₀, p₁, p₂, and n₂ is represented as p₂=k*p₁+m*p₀.

19. The display device of claim 18, wherein
either k is greater than 1 and m equals to 0, or
k equals to 1 and m is greater than 0.

20. The display device of claim 13, wherein the green emission layer includes a second layer adjacent to the first layer,
wherein the second layer of the green emission layer includes the p-type host,
wherein adjacent blue emission layer or red emission layer does not have a second layer including the p-type host.
